(19) United States
(12) Patent Application Publication
(10) Pub. No.: US 2019/0080638 A1
(43) Pub. Date: Mar. 14, 2019

(54) CIRCUIT APPLIED TO DISPLAY APPARATUS AND ASSOCIATED SIGNAL PROCESSING METHOD

(71) Applicant: MStar Semiconductor, Inc., Hsinchu Hsien (TW)

(72) Inventors: Tzu-Yi Yang, Hsinchu County (TW); Ko-Yin Lai, Hsinchu County (TW); Tai-Lai Tung, Hsinchu County (TW)

(21) Appl. No.: 15/968,792

(22) Filed: May 2, 2018

(30) Foreign Application Priority Data
Sep. 13, 2017 (TW) 106131312

(51) Int. Cl. G09G 3/00; H04L 25/08; H04L 25/03; H04B 17/336; G09G 3/20; G06T 3/40

(52) U.S. Cl. CPC G09G 3/006; H04L 25/08; H04L 25/03159; H03H 11/04; G09G 3/2014; G06T 3/40; H04B 17/336

(57) ABSTRACT

A circuit applied to a display apparatus includes an analog-to-digital converter (ADC), a filter and impulsive interference detecting circuit. The ADC converts an analog input signal to a digital input signal. The filter filters out adjacent-channel interference (ACI) of the digital input signal to generate a filtered digital input signal. The impulsive interference detecting circuit detects a noise intensity of a part of a frequency range of the filtered digital input signal to generate a detection result. The part of the frequency range is smaller than a frequency band of the filter, and the detection result is used to determine whether the analog input signal has impulsive interference.

This application claims the benefit of Taiwan application Serial No. 106131312, filed Sep. 13, 2017, the subject matter of which is incorporated herein by reference.

### BACKGROUND OF THE INVENTION

### Field of the Invention

The invention relates in general to signal processing in a display apparatus, and more particularly to an impulsive interference detecting circuit applied to a display apparatus and an associated signal processing method.

### Description of the Related Art

In the Digital Video Broadcasting—Second Generation Terrestrial (DVB-T2) standard, impulsive interference is regarded as an issue that severely affects image display. Impulsive interference has large sudden and periodical amplitudes, and is usually generated by factors in the ambient environment, e.g., an operating washing machine or dishwasher, and a fast automobile passing by. In prior art, whether a received signal has impulsive interference is determined by means of detecting whether a surging high-power amplitude occurs in the signal. However, because a filter in an analog front-end provided at the receiver cannot completely filter out adjacent-channel interference (ACI), a signal may be misjudged as having impulsive interference due to the effect of ACI. Further, when the energy of impulsive interference is weak, ACI further undesirably affects the determination for impulsive interference.

### SUMMARY OF THE INVENTION

Therefore, it is an object of the present invention to provide a circuit applied to a display apparatus and an associated signal processing method, which are capable of accurately determining whether a received signal has impulsive interference even under the influence of adjacent-channel interference (ACI) to solve issue of prior art.

A circuit applied to a display apparatus is disclosed according to an embodiment of the present invention. The circuit includes an analog-to-digital converter (ADC), a filter and an impulsive interference detecting circuit. The ADC converts an analog input signal to a digital input signal. The filter filters out ACI of the digital input signal to generate a filtered digital input signal. The impulsive interference detecting circuit detects a noise intensity of a part of a frequency range of the filtered digital signal to generate a detection result. The part of the frequency range is smaller than a frequency band of the filter, and the detection result is used to determine whether the analog input signal has impulsive interference.

A signal processing method applied to a display apparatus is disclosed according to an embodiment of the present invention. The signal processing method includes: converting an analog input signal to a digital input signal; filtering out ACI of the digital input signal by a filter to generate a filtered digital input signal; and detecting a noise intensity of a part of a frequency range of the digital input signal to generate a detection result.

The part of the frequency range of the digital input signal is smaller than a frequency band of the filter, and the detection result is used to determine whether the analog input signal has impulsive interference.

The above and other aspects of the invention will become better understood with regard to the following detailed description of the preferred but non-limiting embodiments. The following description is made with reference to the accompanying drawings.

### BRIEF DESCRIPTION OF THE DRAWINGS

FIG. 1A is a block diagram of a circuit applied to a display apparatus according to an embodiment of the present invention;

FIG. 1B is a detailed block diagram of FIG. 1A according to an embodiment;

FIG. 2 is a schematic diagram of an adjacent-channel interference (ACI) filter filtering a baseband signal;

FIG. 3 is a block diagram of a circuit applied in a display apparatus according to another embodiment of the present invention;

FIG. 4 is a block diagram of a circuit applied in a display apparatus according to another embodiment of the present invention;

FIG. 5 is a schematic diagram of a frequency-domain signal;

FIG. 6 is a block diagram of an impulsive interference detecting circuit according to an embodiment of the present invention;

FIG. 7 is an example of a filter and a variance calculating circuit in FIG. 6; and

FIG. 8 is a flowchart of a signal processing method applied to a display apparatus according to an embodiment of the present invention.

### DETAILED DESCRIPTION OF THE INVENTION

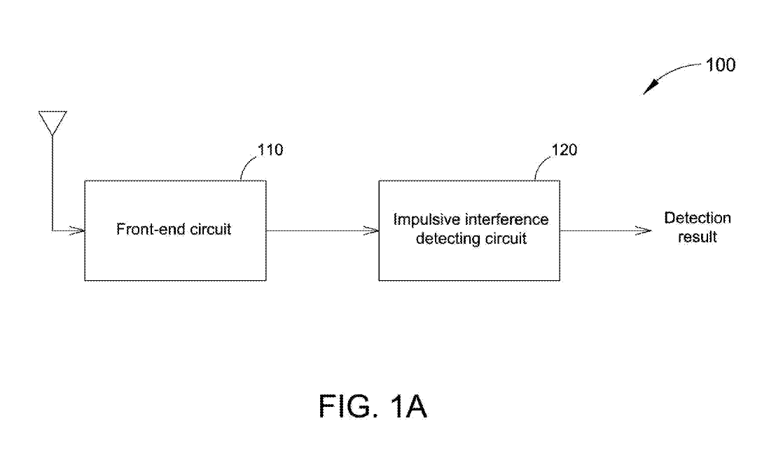

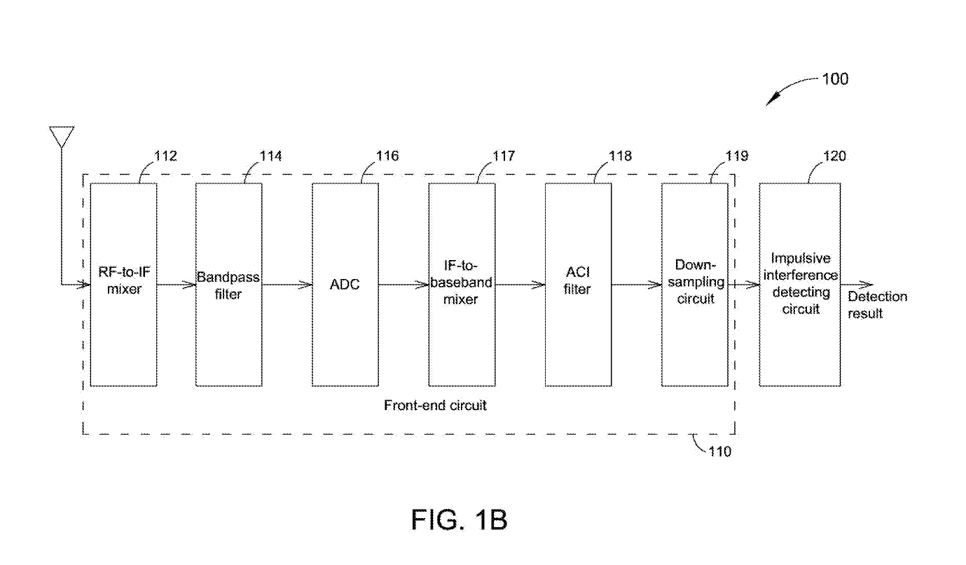

FIG. 1A shows a block diagram of a circuit 100 applied in a display apparatus according to an embodiment of the present invention. In this embodiment, the circuit 100 is disposed in a receiver in a television or a set-top box (STB) compliant to the Digital Video Broadcasting—Second Generation Terrestrial Generation Two (DVB-T2) standard. The circuit 100 receives an analog input signal from an antenna, and generates an impulsive interference detection result. As shown in FIG. 1A, the circuit 100 includes a front-end circuit 110 and an impulsive interference detecting circuit 120. The front-end circuit 110 converts the received analog input signal to a digital input signal, and filters out adjacent-channel interference (ACI) of the digital input signal to generate a filtered digital input signal, for the impulsive interference detecting circuit 120 to detect whether the analog input signal has impulsive interference.

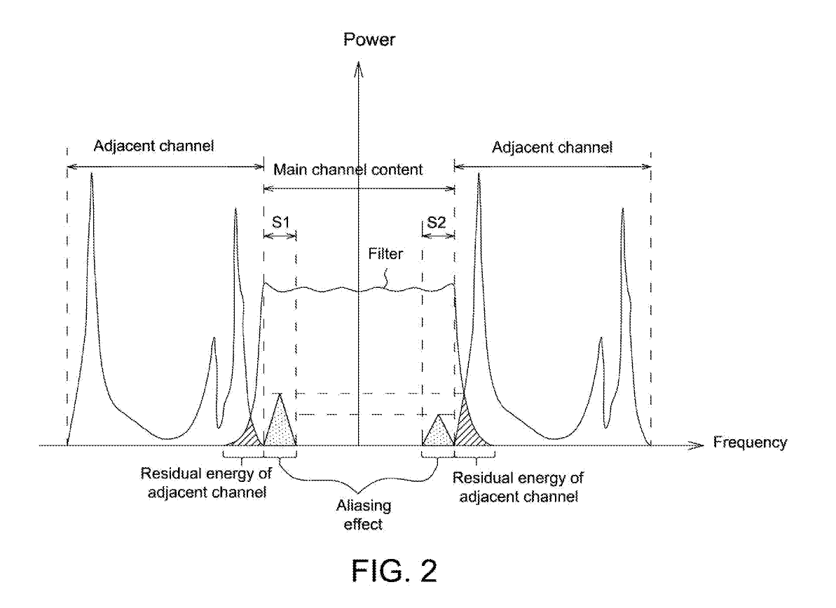

FIG. 1B shows a detailed block diagram of FIG. 1A according to an embodiment. In FIG. 2, the front-end circuit 110 includes a radio-frequency-to-intermediate frequency (RF-to-IF) mixer 112, a bandpass filter 114, an analog-to-digital converter (ADC) 116, an IF-to-baseband mixer 117, an ACI filter 118 and a down-sampling circuit 119. The RF-to-IF mixer 112 converts an analog input signal received from an antenna to an IF signal. The bandpass filter 114 filters the IF signal to generate a filtered IF signal. The ADC 116 performs analog-to-digital conversion on the filtered IF signal to generate a digital input signal. The IF-to-baseband mixer 117 converts the digital input signal to a baseband signal. The ACI mixer 118 filters the baseband signal to filter out a signal component of ACI to generate a filtered baseband signal. The down-sampling circuit 119 performs down-sampling on the filtered baseband signal to generate a filtered digital input signal.

FIG. 2 shows a schematic diagram of the ACI filter 118 filtering the baseband signal. The baseband signal includes a main channel component and adjacent channel components on the two sides. In this embodiment, the main channel component may be a part associated with digital channels in DVB-T2, and the adjacent channels on the two sides may be phase-alternative between line (PAL) channel components. Ideally, the ACI filter 118 is capable of completely filtering out the parts associated with adjacent channels and preserves only the main channel component. However, the ACI filter 118 cannot have a perfect filtering band, and so the filtered baseband signal generated nonetheless includes residual energy of adjacent channels (i.e., the shaded areas in FIG. 2). Due to the presence of the residual energy of adjacent channels, the digital input signal generated from the filtered baseband signal having undergone the down-sampling circuit 119 includes an aliasing effect, i.e., the dotted areas in FIG. 2. The aliasing effect affects subsequent processing or computation performed based on the main channel component.

Therefore, to prevent the influence of the aliasing effect upon subsequent impulsive interference detection, the impulsive interference detecting circuit 120 of the embodiment detects a noise intensity of only a part of a frequency range of the filtered digital input signal to generate a detection result. In this embodiment, the part of the frequency range detected does not include the range affected by the aliasing effect; that is, the part of the frequency range detected does not include, in the frequency range corresponding to the main channel component, a range having a minimum frequency interval (i.e., the frequency interval S1 in FIG. 2) and a range having a maximum frequency interval (i.e., the frequency interval S2 in FIG. 2). Since the part of the frequency range detected by the impulsive interference detecting circuit 120 does not include the frequency intervals S1 and S2 affected by the aliasing effect, the detection result generated is able to accurately reflect whether the analog input signal has impulsive interference, preventing the aliasing effect from causing misjudgment.

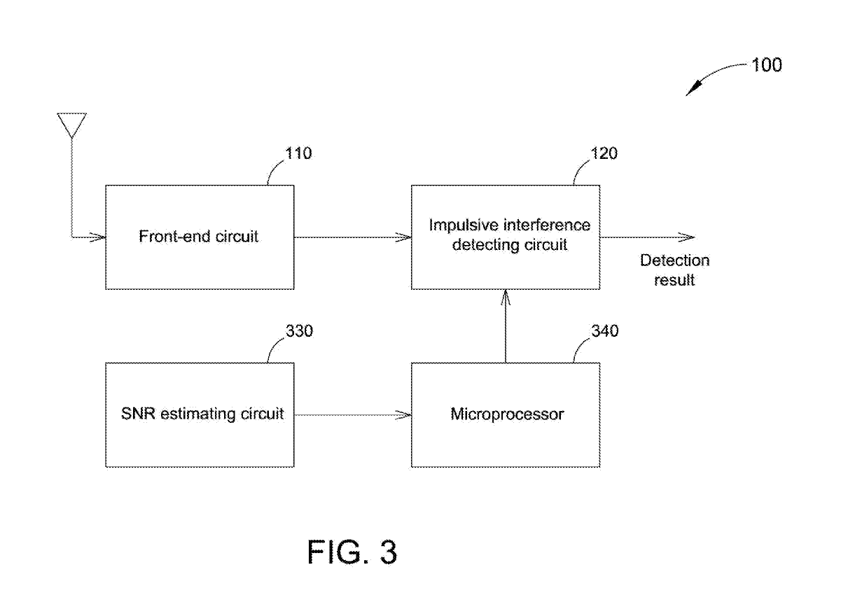

In this embodiment, the ranges of the frequency intervals S1 and S2 may be directly set as constant frequency intervals. In another embodiment, the ranges of the frequency intervals S1 and S2 are dynamically configured according to a noise intensity of a signal. More specifically, referring to FIG. 3, the circuit 100 can further include a signal-to-noise ratio (SNR) estimating circuit 330 and a microprocessor 340. The SNR estimating circuit 330 can detect a noise intensity or an SNR of the analog input signal or a reference signal associated with the analog input signal in the circuit 100 (e.g., the filtered digital input signal generated by the front-end circuit or a more back-end signal). The microprocessor 340 dynamically adjusts the ranges of the frequency intervals S1 and S2 according to the estimated noise intensity or SNR. For example, the microprocessor 340 can increase the ranges of the frequency intervals S1 and S2 as the noise intensity or SNR gets lower. Although adjusting the ranges of the frequency intervals S1 and S2 is given as an example, one person skilled in the art can understand that, directly setting, or determining the part of the frequency range detected by the impulsive interference detecting circuit 120 according to the noise intensity of the detection result of the SNR estimating circuit 330, can also achieve the same effect.

As described above, with the method in the above embodiments, the issue being subsequently incapable of accurately detecting impulsive interference because the ACI filter 118 cannot completely filter out the ACI component can be reliably eliminated, thus improving the detection accuracy of the impulsive interference detecting circuit 120.

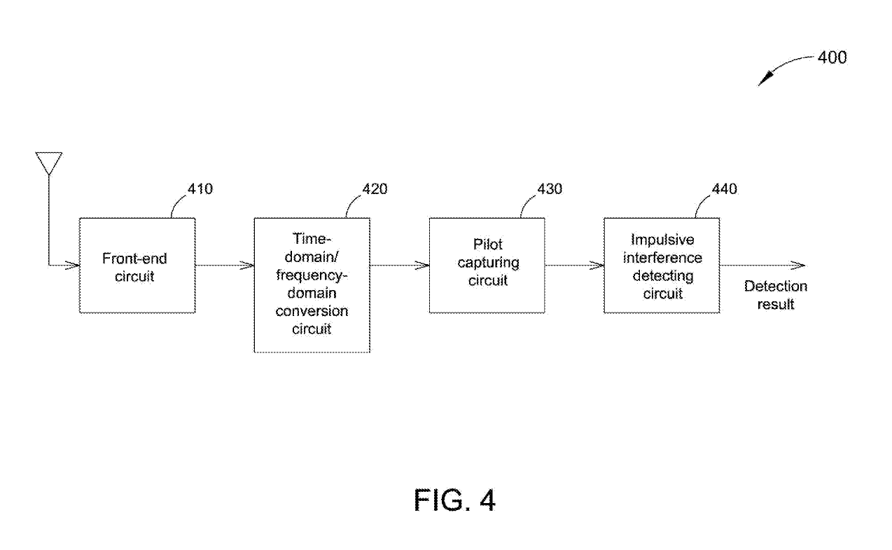

Further, when the energy of impulsive interference is weak, impulsive interference detection is susceptible to detection inaccuracy. Therefore, the present invention further provides an embodiment tailoring to dense impulsive interference having a weaker energy so as to more accurately detect impulsive interference. FIG. 4 shows a block diagram of a circuit 400 applied in a display apparatus according to an embodiment of the present invention. As shown in FIG. 4, the circuit 400 includes a front-end circuit 410, a time-domain/frequency-domain conversion circuit 420, a pilot capturing circuit 430 and an impulsive interference detecting circuit 440.

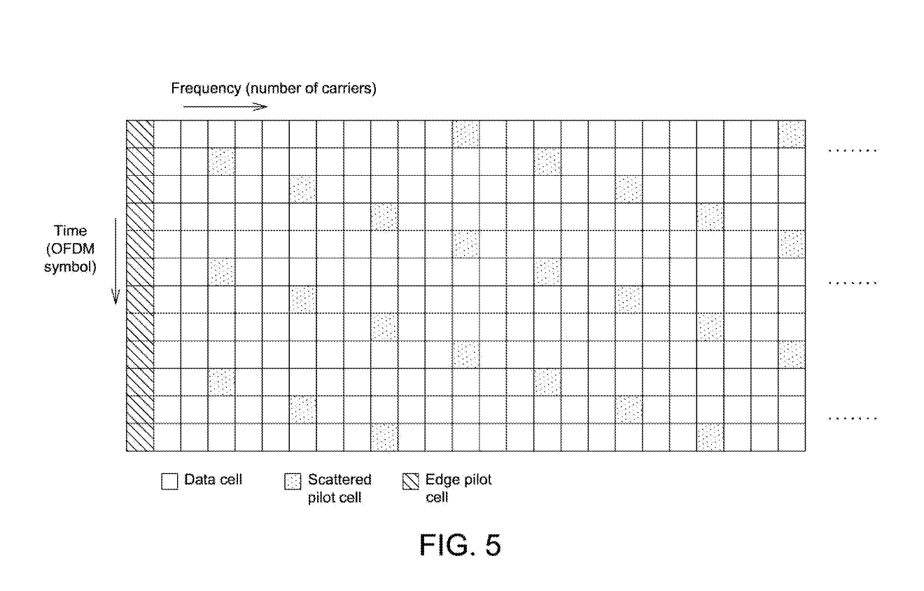

In the circuit 440, the front-end circuit 410 is similar to the front-end circuit 110 in FIG.1A. The time-domain/frequency-domain conversion circuit 420 converts the filtered digital input signal from a time domain to a frequency domain to generate a frequency-domain signal. The time-domain/frequency-domain conversion circuit 420 can be achieved by a fast Fourier transform (FFT) operation. Referring to FIG. 5 showing a schematic diagram of the frequency-domain signal, the vertical axis represents OFDM symbols at different time points, each row is one OFDM symbol, and each OFDM symbol includes an edge pilot cell, multiple data cells and multiple scattered pilot cells; the horizontal axis represents frequency, and each column corresponds to different carriers. The pilot capturing circuit 430 captures multiple pilot cells (which may be edge plot cells and/or scattered pilot cells, and are exemplified by scattered pilot cells in the description below) of one symbol from the frequency-domain signal. The impulsive interference detecting circuit 440 determines whether the symbol has impulsive interference according to noise intensities of the pilot cells to generate a detection result.

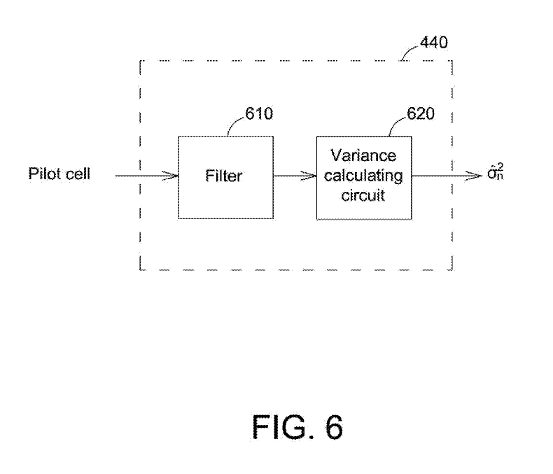

FIG. 6 shows a block diagram of the impulsive interference detecting circuit 440 according to an embodiment of the present invention. In this embodiment, the impulsive interference detecting circuit 440 sequentially generates variance statistical information of noise of pilot cells of each symbols (i.e., the OFDM symbol of each row in FIG. 5), and accordingly generates a detection result. As shown in FIG. 6, the impulsive interference detecting circuit 440 includes a filter 610 and a variance calculating circuit 620. The filter 610 filters out the signal to be transmitted and transmits the component of noise, and the variance calculating circuit 620 performs variance calculation according to the component of noise.

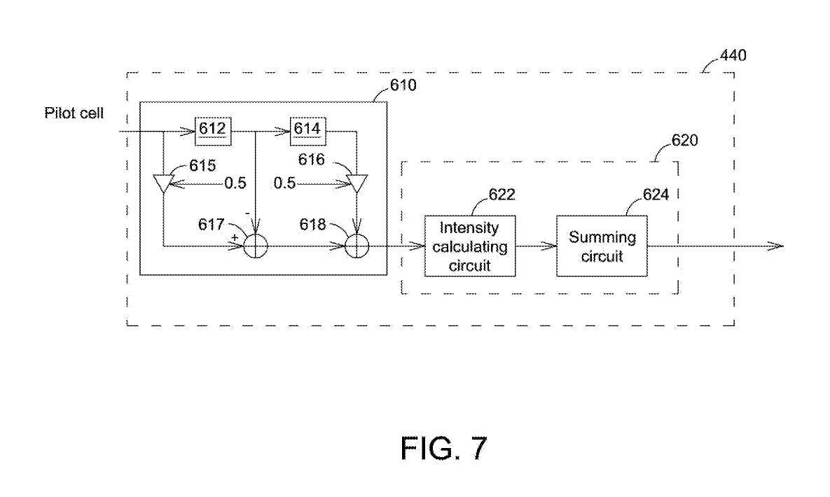

FIG. 7 shows a detailed block diagram of the impulsive interference detecting circuit 440 according to an embodiment. In this embodiment, the filter 610 is exemplified by a second-order filter, and so the filter 610 of this embodiment includes two delay circuits 612 and 614, two multipliers 615 and 616 (each having a multiplier of “0.5”), and two adders 617 and 618. However, the present invention is not limited to the above. In other embodiments, the filter 610 may be a filter having more than two orders. The variance calculating circuit 620 includes an intensity calculating circuit 622 and a summing circuit 624. Individual operations of the components are described by means of equations below.

A channel frequency response of the pilot cells captured by the pilot capturing circuit 430 may be represented as: Ĥ_{n,k}=H_{n,k}+N_{n,k}, where the subscript “n” represents the order of the symbol (i.e., which row in FIG. 5), the subscript “k” represents the number of the carrier (i.e., which column in FIG. 5), H_{n,k} represents the channel frequency response of the pilot cells, and N_{n,k} represents noise of the pilot cells. Further, the channel impulse response of the pilot cells can be represented as

$$h ( t ) = {\sum }_{m = 0}^{M - t} δ ( t - {τ}_{m} ) \cdot {e}^{j {θ}_{m}} ,$$

where δ(t) is a delta function, τₘ, and θₘ are corresponding path delay and phase, and M is the number of paths. The filter 610 filters out the channel component of the pilot cells to capture the noise component of the pilot cells. More specifically, the output of the filter 610 may be represented as: Hₖ^{diff}=δ[k]−0.5·(δ[k+1]+δ[k−1]), which is correspondingly, in the time domain,

$${h}^{diff} ( t ) = 1 - cos ( 2 π \frac{t}{{T}_{sp}} ) .$$

Thus, the output of the filter 610 may be represented as:

$$\begin{matrix}{\hat{H}}_{n , k} - 0.5 ( {\hat{H}}_{n , k - 1} + {\hat{H}}_{n , k + 1} ) = ( δ [ k ] - 0.5 \cdot ( δ [ k + 1 ] + δ [ k - 1 ] ) ) ⊗ {\hat{H}}_{n , k} \\ = {H}_{k}^{diff} ⊗ {\hat{H}}_{n , k} \\ = {H}_{k}^{diff} ⊗ ( {H}_{n , k} + {n}_{n , k} ) \\ = {H}_{k}^{diff} ⊗ {H}_{n , k} + {H}_{k}^{diff} ⊗ {N}_{n , k} \\ \approx {H}_{k}^{dif} ⊗ {N}_{n , k} \\ = {N}_{n , k} - 0.5 ( {N}_{n , k + 1} + {N}_{n , k + 1} ) .\end{matrix}$$

In brief, the data outputted by the filter 610 each time is a difference between the noise component of one pilot cell and the average of the noise components of two left and right adjacent pilot cells.

Next, the variance calculating circuit 620 calculates the variance statistical information of the noise of the pilot cells of each symbol. To prevent the influence associated with the aliasing effect described previously, for each symbol, the variance statistical information is calculated according to the noise of a part of the pilot cells; that is, in the process of calculating the variance statistical information, pilot cells corresponding to a minimum frequency interval (e.g., S1 in FIG. 2) and a maximum frequency interval (e.g., S2 in FIG. 2) are eliminated. More specifically, the intensity calculating circuit 622 calculates a difference between the noise outputted by the filter 610, e.g., the intensity calculating circuit 622 calculates the square of the output of the filter 610 and uses the square as its output. The summing circuit 624 sums a part of the output of the intensity calculating circuit 622 (i.e., eliminating the output corresponding to the minimum frequency interval and the maximum frequency interval) to generate the variance statistical information. In this embodiment, the impulsive interference detecting circuit 440 further includes a scaling circuit (not shown), which scales the variance statistical information to generate a detection result. More specifically, a calculation equation of the filter 610, the intensity calculating circuit 622, the summing circuit 624 and the scaling circuit can be represented as:

$$E \{ {\hat{σ}}_{n}^{2} \} = \frac{2}{3} \frac{1}{K max - K min} {\sum }_{k = K min}^{K max} {\vert {N}_{n , k} - \frac{1}{2} ( {N}_{n , k - 1} + {N}_{n , k + 1} ) \vert}^{2} .$$

The above equation further describes how the scaling circuit processes multiple sets of variance statistical information outputted by the variance calculating circuit 620 to generate the detection result, where “Kmax” represents the number of the pilot cell, among the pilot cells, having a maximum frequency (i.e., a frequency closest to the frequency interval S2 in FIG. 2), “Kmin” represents the number of the pilot cell, among the pilot cells, having a minimum frequency (i.e., a frequency closets to the frequency interval S1 in FIG. 1), “Kmax-Kmin” represents the quantity of pilot cells used for the calculation, and

$$″ \frac{2}{3} \frac{1}{K max - K min} ″$$

represents the adjustment ratio of the scaling circuit. If the noise variance of each pilot cell is defined as σ_{n,k}²≡E{|n_{n,k}|²}, the calculation equation of the filter 610, the intensity calculating circuit 622, the summing circuit 624 and the scaling circuit can be represented as:

$$E \{ {\hat{σ}}_{n}^{2} \} = \frac{2}{3} \frac{1}{K max - K min} {\sum }_{k = K min}^{K max} E \{ {\vert {n}_{n , k} \vert}^{2} + \frac{1}{4} ( {\vert {n}_{n , k - 1} \vert}^{2} + {\vert {n}_{n , k + 1} \vert}^{2} ) - Re \{ {n}_{n , k} ( {n}_{n , k - 1}^{′} + {n}_{n , k + 1}^{′} ) + \frac{1}{2} {n}_{n , k - 1} {n}_{n , k + 1}^{′} \} \} = \frac{2}{3} \frac{1}{K max - K min} {\sum }_{k = K min}^{K max} ( {σ}_{n , k}^{2} + \frac{1}{4} {σ}_{n , k - 1}^{2} + \frac{1}{4} {σ}_{n , k + 1}^{2} ) = \frac{1}{K max - K min} {\sum }_{k = K min}^{K max} {σ}_{n , k}^{2} - \frac{1}{6 ( K - 2 )} ( 5 {σ}_{n , 0}^{2} + 5 {σ}_{n , K - 1}^{2} + {σ}_{n , 1}^{2} + {σ}_{n , K - 2}^{2} )$$

The noise variance of the symbol is again defined as the average of the variance of each pilot cell, and the noise variance of the symbol can be represented as:

$${\overline{σ}}_{n}^{2} ≡ \frac{1}{K max - K min} {\sum }_{k = K min}^{K max} {σ}_{n , k}^{2} .$$

If the value of (Kmax-Kmin) is large, the output of the impulsive interference detecting circuit 440 can be represented as:

$$E \{ {\hat{σ}}_{n}^{2} \} = ( \frac{1}{K max - K min} {\sum }_{k = K min}^{K max} {σ}_{n , k}^{2} ) - \underline{\frac{1}{6 ( K - 2 )} ( 5 {σ}_{n , 0}^{2} + 5 {σ}_{n , K - 1}^{2} + {σ}_{n , 1}^{2} + {σ}_{n , K - 2}^{2} )} \to \frac{1}{K max - K min} {\sum }_{k = K min}^{K max} {σ}_{n , k}^{2} = {\overline{σ}}_{n}^{2} .$$

As described above, the impulsive interference detecting circuit 440 is capable of reliably outputting the average of the noise variance of each carrier frequency in each symbol as the detection result.

Further, “Kmax” and “Kmin” can be directly set as constant numbers, or similar to the circuit 100 in the embodiment in FIG. 3, the numbers of “Kmax” and “Kmin” can be dynamically adjusted according to an estimated noise intensity or SNR by a microprocessor, so as to determine the ranges of the frequency intervals S1 and S2 that are not detected by the impulsive interference detecting circuit 440. For example, as the noise intensity gets stronger or the SNR gets lower, “Kmax” can be decreased and “Kmin can be increased, such that the ranges of the frequency intervals S1 and S2 that are not detected by the impulsive interference detecting circuit 440 are increased.

Noise of each pilot cell includes common noise and noise caused by impulsive interference. Common noise may include the abovementioned additive white Gaussian noise (AWGN), inter-carrier interference (ICI), adjacent-channel interference (ACI) and co-channel interference (CCI). Thus, the noise variance that the impulsive interference detecting circuit 440 outputs with respect to each symbol in fact includes common noise and impulsive interference. However, in the above calculation process, particularly noticeable values are generated based on a sporadic property of impulsive interference. Thus, the method according to the embodiment can more accurately determine whether each symbol is affected by impulsive interference.

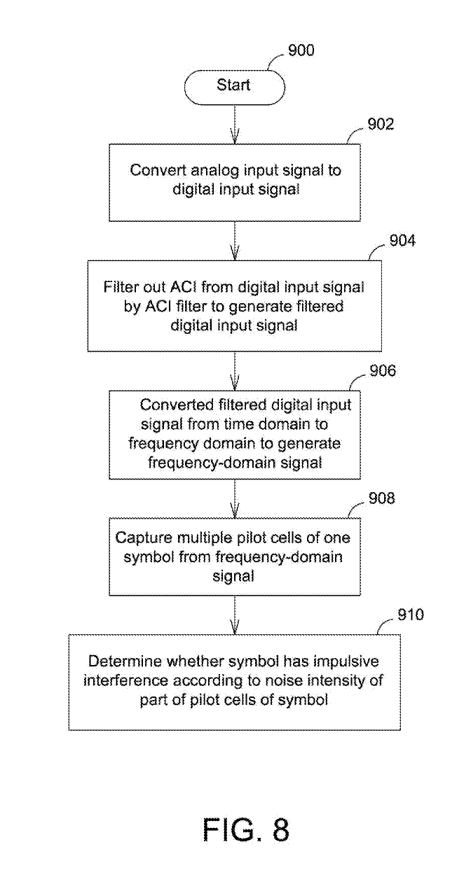

FIG. 8 shows a flowchart of a signal processing method applied to a display apparatus according to an embodiment of the present invention. Referring to the disclosure associated with FIG. 1 to FIG. 7, the process in FIG. 8 is as below.

In step 900, the process begins.

In step 902, an analog input signal is converted to a digital input signal.

In step 904, adjacent channel interference (ACI) of the digital input signal is filtered out by means of an ACI filter to generate a filtered digital input signal.

In step 906, the filtered digital input signal is converted from a time domain to a frequency domain to generate a frequency-domain signal.

In step 908, multiple pilot cells of one symbol are captured from the frequency-domain signal.

In step 910, whether the symbol has impulsive interference is determined according to noise intensities of a part of the multiple pilot cells in the symbol.

In summary, in the circuit applied to a display apparatus of the present invention, a frequency range affected by an aliasing effect is eliminated, such that the accuracy of impulsive interference detection of the impulsive interference detecting circuit is significantly enhanced. Further, by performing impulsive interference detecting additionally based on pilot cells captured from a frequency-domain signal, detection accuracy can be maintained even in a situation of dense impulsive interference having a weaker energy.

While the invention has been described by way of example and in terms of the preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A circuit applied to a display apparatus, comprising:
an analog-to-digital converter (ADC), converting an analog input signal to a digital input signal;
a filter, filtering out adjacent channel interference (ACI) of the digital input signal to generate a filtered digital input signal; and
an impulsive interference detecting circuit, detecting a noise intensity of a part of a frequency range of the filtered digital input signal to generate a detection result, wherein the part of the frequency range is smaller than a frequency band corresponding to the filter, and the detection result is for determining whether the analog input signal has impulsive interference.

2. The circuit according to claim 1, wherein the part of the frequency range does not include a range of a minimum frequency interval and a range of a maximum frequency interval in the frequency band corresponding to the filter.

3. The circuit according to claim 2, further comprising:
a microprocessor, controlling the range of the minimum frequency interval and/or the range of the maximum frequency interval.

4. The circuit according to claim 3, wherein the microprocessor determines the range of the minimum frequency interval and/or the range the maximum frequency interval according to a noise intensity of the analog input signal or a noise intensity of a reference signal associated with the analog input signal.

5. The circuit according to claim 4, wherein the microprocessor determines the range of the minimum frequency interval and/or the range of the maximum frequency interval according to a signal-to-noise ratio (SNR) of the analog input signal or an SNR of a reference signal associated with the analog input signal.

6. The circuit according to claim 4, wherein when the noise intensity of the analog input signal or the noise intensity of the reference signal associated with the analog input signal gets stronger, the range of the minimum frequency interval and/or the range the maximum frequency interval determined by the microprocessor is/are larger.

7. The circuit according to claim 1, further comprising:
a time-domain/frequency-domain converter, converting the filtered digital input signal from a time domain to a frequency domain to generate a frequency-domain signal, wherein the frequency-domain signal comprises a plurality of symbols, each of which comprises a plurality of pilot cells; and
a pilot cell capturing circuit, capturing the plurality of pilot cells of one of the plurality of symbols from the frequency-domain signal;
wherein, the impulsive interference detecting circuits generates the detection result according to noise intensities of a part of the plurality of pilot cells of the symbol.

8. The circuit according to claim 7, wherein the filter is a first filter, and the impulsive interference detecting circuit comprises:
a second filter, filtering the plurality of pilot cells of the symbol to filter out a channel component of the plurality of pilot cells, and outputting a noise component; and
a variance calculating circuit, calculating variance statistical information of the noise intensities of the part of the plurality of pilot cells according to the noise component;
wherein, the detection result is generated according to the variance statistical information.

9. The circuit according to claim 8, wherein the second filter is a multi-order filter and calculates a variance corresponding to each of the plurality of pilot cells according to the pilot cell and the adjacent pilot cells of the plot cell, and the variance calculating circuit comprises:
an intensity calculating circuit, calculating an intensity value of the variance corresponding to each of the plurality of pilot cells; and
a summing circuit, summing the intensity values of the variances corresponding to the part of the plurality of pilot cells to obtain the variance statistical information.

10. The circuit according to claim 8, wherein the impulsive inference detecting circuit further comprises:
a scaling circuit, scaling the variance statistical information to serve as the detection result.

11. A signal processing method applied to a display apparatus, comprising:
converting an analog input signal to a digital input signal;
filtering out adjacent channel interference (ACI) from the digital input signal by a filter to generate a filtered digital input signal; and
detecting a noise intensity of a part of a frequency range of the filtered digital input signal to generate a detection result, wherein the part of the frequency range is smaller than a frequency band corresponding to the filter, and the detection result is for determining whether the analog input signal has impulsive interference.

12. The signal processing according to claim 11, wherein the part of the frequency range does not include a range of the minimum frequency interval and a range of a maximum frequency interval in the frequency band corresponding to the filter.

13. The signal processing according to claim 12, further comprising:
dynamically controlling the range of the minimum frequency interval and/or the range the maximum frequency interval.

14. The signal processing according to claim 13, wherein the step of dynamically controlling the range of the minimum frequency interval and/or the range the maximum frequency interval comprises:
determining the range of the minimum frequency interval and/or the range the maximum frequency interval according to a noise intensity of the analog input signal or a noise intensity of a reference signal associated with the analog input signal.

15. The signal processing according to claim 14, wherein the step of dynamically controlling the range of the minimum frequency interval and/or the range the maximum frequency interval comprises:
determining the range of the minimum frequency interval and/or the range the maximum frequency interval according to a SNR of the analog input signal or an SNR of a reference signal associated with the analog input signal.

16. The signal processing according to claim 14, wherein when the noise intensity of the analog input signal or the noise intensity of the reference signal associated with the analog input signal gets stronger, the range of the minimum frequency interval and/or the range the maximum frequency interval determined by the microprocessor is/are larger.

17. The signal processing according to claim 11, further comprising:
converting the filtered digital input signal from a time domain to a frequency domain to generate a frequency-domain signal, wherein the frequency-domain signal comprises a plurality of symbols, each of which comprises a plurality of pilot cells; and
capturing the plurality of pilot cells of one of the plurality of symbols from the frequency-domain signal;
wherein the step of detecting the noise intensity of the part of the frequency range of the filtered digital input signal comprises:
generating the detection result according to noise intensities of a part of the plurality of pilot cells of the symbol.

18. The signal processing according to claim 17, wherein the step of generating the detection result according to the noise intensities of the part of the plurality of pilot cells of the symbol comprises:
filtering the plurality of pilot cells of the symbol to filter out a channel component of the plurality of pilot cells, and outputting a noise component;
calculating variance statistical information of the noise intensities of the part of the plurality of pilot cells according to the noise component; and
generating the detection result according to the variance statistical information.

19. The signal processing according to claim 18, wherein the step of filtering the plurality of pilot cells of the symbol to generate the filtered signal is performed by a multi-order filter, and the multi-order filter calculates a variance corresponding to each of the plurality of pilot cells according to the pilot cell and the adjacent pilot cells thereof; and the step of calculating the variance statistical information of the noise intensities of the part of the plurality of pilot cells comprises:
calculating an intensity value of the variance corresponding to each of the plurality of pilot cells; and
summing the intensity values of the variances corresponding to the part of the plurality of pilot cells to obtain the variance statistical information.

20. The signal processing according to claim 18, wherein the step of generating the detection result according to the variance statistical information comprises:
scaling the variance statistical information to serve as the detection result.
